(19) United States
(12) Patent Application Publication
(10) Pub. No.: US 2015/0007874 A1
(43) Pub. Date: Jan. 8, 2015

(54) BACK-CONTACT SOLAR CELL MODULE

(71) Applicant: E I DU Pont De Nemours And Company, Wilmington, DE (US)

(72) Inventors: ISAO HAYASHI, Tokyo (JP); HIDEKI AKIMOTO, Kanagawa (JP)

(21) Appl. No.: 13/933,297

(22) Filed: Jul. 2, 2013

(51) Int. Cl. H01L 31/0224

(52) U.S. Cl. CPC H01L 31/022441
USPC 136/256; 438/64

(57) ABSTRACT

A back-contact solar cell module, comprising: silicon wafer having a sunlight receiving surface and a rear surface, wherein n+ region and p+ region are formed on the rear surface; an n+ electrode formed on the n+ region of the silicon wafer; a p+ electrode formed on the p+ region of the silicon wafer; a printed wiring board comprising a substrate, a cathode and an anode, being placed in a way that the anode and the cathode are in contact with the n+ electrode and the p+ electrode respectively; wherein at least one of the n+ electrode and the p+ electrode, prior to firing, comprises a conductive composition comprising 11.0-39.9 wt % of silver particles, 10.0-40.0 wt % of glass frit, and 0.5-20.0 wt % of palladium particles, based on total weight of the composition.

### FIELD OF THE INVENTION

The present invention relates to a back-contact solar cell module.

### TECHNICAL BACKGROUND OF THE INVENTION

Recently, studies have been conducted on back-contact solar cells for the purpose of further enhancing the power generation efficiency of solar cells. Back-contact solar cells refer to solar cells in which the electrodes are formed on the opposite side from the sunlight receiving side, thereby making it possible to increase the light receiving surface since the electrodes are not formed on the light receiving surface.

Of such back-contact solar cells, a solar cell that can be produced at an especially high production efficiency and shows a high photoelectric conversion efficiency has been attracting attention particularly in recent years (see, for example, Japanese Patent Application Laid-open No. 2009-266958). This back-contact solar cell is assembled into a solar cell module by disposing such solar cells on a board 600 on which wiring having the structure diagrammatically shown in FIG. 6 has been formed, so that the n electrode (n+ electrode) and p electrode (p+ electrode) formed on the rear surface of each solar cell are electrically connected respectively to wiring lines (anode) 602 for n electrodes (n+ electrodes) and to wiring lines (cathode) 601 for p electrodes (p+ electrodes) in the board 600. A paste to be applied to the back contact-type solar cell is disclosed in U.S. Pat. No. 7,959,831.

### SUMMARY OF THE INVENTION

In one embodiment, the present invention relates to a back-contact solar cell module, comprising: silicon wafer having a sunlight receiving surface and a rear surface, wherein n+ region and p+ region are formed on the rear surface; an n+ electrode formed on the n+ region of the silicon wafer; a p+ electrode formed on the p+ region of the silicon wafer; a printed wiring board comprising a substrate, a cathode and an anode, being placed in a way that the anode and the cathode are in contact with the n+ electrode and the p+ electrode respectively; wherein at least one of the n+ electrode and the p+ electrode, prior to firing, comprises a conductive composition comprising 11.0-39.9 wt % of silver particles, 10.0-40.0 wt % of glass frit, and 0.5-20.0 wt % of palladium particles, based on total weight of the composition.

In another aspect, the present invention relates to a method for manufacturing back-contact solar cell module, comprising the steps of: providing a silicon wafer having a sunlight receiving surface and a rear surface, wherein n+ region and p+ region are formed on the rear surface; applying a first conductive composition on the n+ region of the silicon wafer; applying a second conductive composition on the p+ region of the silicon wafer; firing the first conductive composition and the second conductive composition to form an n+ electrode on the n+ region of the silicon wafer and a p+ electrode on the p+ region of the silicon wafer; and placing a printed wiring board comprising a substrate, a cathode and an anode on the rear surface of the silicon wafer in a way that the anode and the cathode are in contact with the n+ electrode and the p+ electrode respectively; wherein at least one of the first conductive composition and the second conductive composition comprises a conductive composition comprising 11.0-39.9 wt % of silver particles, 10.0-40.0 wt % of glass frit, and 0.5-20.0 wt % of palladium particles, based on total weight of the composition.

The back-contact solar cell module of the present invention has low contact resistance between the electrodes and semiconductor, and has superior power generation characteristics.

### BRIEF DESCRIPTION OF THE DRAWINGS

FIG. 1A is a cross-sectional schematic drawing of a portion of a back-contact solar cell module. FIG. 1B is an overhead view of a back-contact solar cell showing an electrode pattern on the side opposite from a light receiving side.

FIGS. 2A to 2E are drawings for explaining a production process when producing a back-contact solar cell.

FIGS. 3A to 3E are drawings for explaining a production process when producing a back-contact solar cell.

FIGS. 4A to 4D are drawings for explaining a production process when producing a back-contact solar cell.

FIGS. 5A to 5C are drawings for explaining a production process when producing a back-contact solar cell.

FIG. 6 is a plan view which shows an example of the printed wiring board employed in a solar cell module having a high photoelectric conversion efficiency.

FIG. 7 shows a plan view of a mask for use in pattern-wise printing a conductive composition on a silicon substrate when a value of contact resistance (Re) between an electrode to be formed on the silicon substrate using the conductive composition and the silicon substrate is measured.

### DETAILED DESCRIPTION OF THE INVENTION

The present invention is explained in detail below.

### A Back-Contact Solar Cell Module

In one embodiment, the back-contact solar cell module comprises a silicon wafer, an n+ electrode and a p+ electrode, and a printed wiring board.

Silicon Wafer

In one embodiment, the silicon wafer has a sunlight receiving surface and a rear surface. In one embodiment, the sunlight receiving surface can be formed as a textured structure, and the surface thereof is covered with an anti-reflective film. In one embodiment, the anti-reflective film can be a thin film composed of, for example, titanium dioxide (TiO₂) and silicon dioxide (SiO₂). On the rear surface, an n+ region and a p+ region are formed.

Electrodes

The n+ electrode is formed on the n+ region of the silicon wafer and the p+ electrode is formed on the p+ region of the silicon wafer. In one embodiment, these electrodes comprise a conductive composition comprising silver particles, palladium particles and glass frit, prior to firing. In addition, the conductive composition may comprise organic medium and additives.

1. Silver Particles

In one embodiment, the silver particles may be in the shape of flakes, spheres or they may be amorphous. Although there are no particular limitations on the particle diameter of the silver particles from the viewpoint of technical effects in the case of being used as an ordinary electrically conductive paste, particle diameter has an effect on the firing characteristics of the silver (for example, silver particles having a large particle diameter are sintered at a slower rate than silver particles having a small particle diameter).

Thus, the mean particle size (D50) of the silver particles actually used may be determined according to the firing profile. In one embodiment, the mean particle size (D50) of the silver particles is 0.1-10 μm, 1-5 μm in another embodiment. In one embodiment, two or more types of silver particles having different mean particle sizes (D50) may be used as a mixture. Normally, the silver has a high purity (greater than 99%). However, substances of lower purity can be used depending on the electrical requirements of the electrode pattern. In one embodiment, the content of the silver particles is 11.0-39.9 wt %, based on the total weight of the composition, prior to firing. In another embodiment, the content of the silver particles is 13.0-39.0 wt %, based on the total weight of the composition, prior to firing. In a further embodiment, the content of the silver particles is 13.0-38.0 wt %, based on the total weight of the composition, prior to firing. In the invention, so long as the content of the silver particles is in the range of 11.0-39.9 wt %, a back-contact solar cell module which includes electrodes that have excellent conductivity and are excellent also in terms of low contact resistance, i.e., that combine the two properties, is provided.

2. Palladium Particles

In one embodiment, the palladium particles may be in the shape of spheres. In one embodiment, the mean particle size (D50) of the palladium particles is 0.1-5.0 μm, 0.1-3.0 μm in another embodiment. In one embodiment, two or more types of palladium particles having different mean particle sizes (D50) may be used as a mixture.

The palladium purity in the palladium particles is, for example, 85% or higher. In one embodiment, palladium alloys such as Ag/Pd alloys and Pt/Pd alloys may be used. In one embodiment, examples of compositional ratios in these alloys include 60/40 to 95/5 for the Ag/Pd alloys and 5/95 to 15/85 for the Pt/Pd alloys.

In one embodiment, the content of the palladium particles is 0.5-20.0 wt %, based on the total weight of the composition, prior to firing. In another embodiment, the content of the palladium particles is 0.7-18.6 wt %, based on the total weight of the composition, prior to firing. In the invention, so long as the content of the palladium particles is in the range of 0.5-20 wt %, a back-contact solar cell module which includes electrodes that combine satisfactory conductivity with low contact resistance is provided.

3. Glass Frit

Since the chemical composition of the glass frit is not important in the present invention, any glass frit can be used provided it is a glass frit used in electrically conductive pastes for electronic materials. For example, lead borosilicate glass can be used. Lead borosilicate glass is a superior material from the standpoint of both the range of the softening point and glass adhesion. In addition, lead-free glass, such as a bismuth silicate lead-free glass, can also be used. In one embodiment, the content of the glass frit is 10.0-40.0 wt %, based on the total weight of the composition, prior to firing. In another embodiment, the content of the glass frit is 13.0-28.0 wt %, based on the total weight of the composition, prior to firing. In the invention, by setting the glass frit content at a value within the range shown above, a back-contact solar cell module including electrodes which combine satisfactory conductivity with low contact resistance is provided.

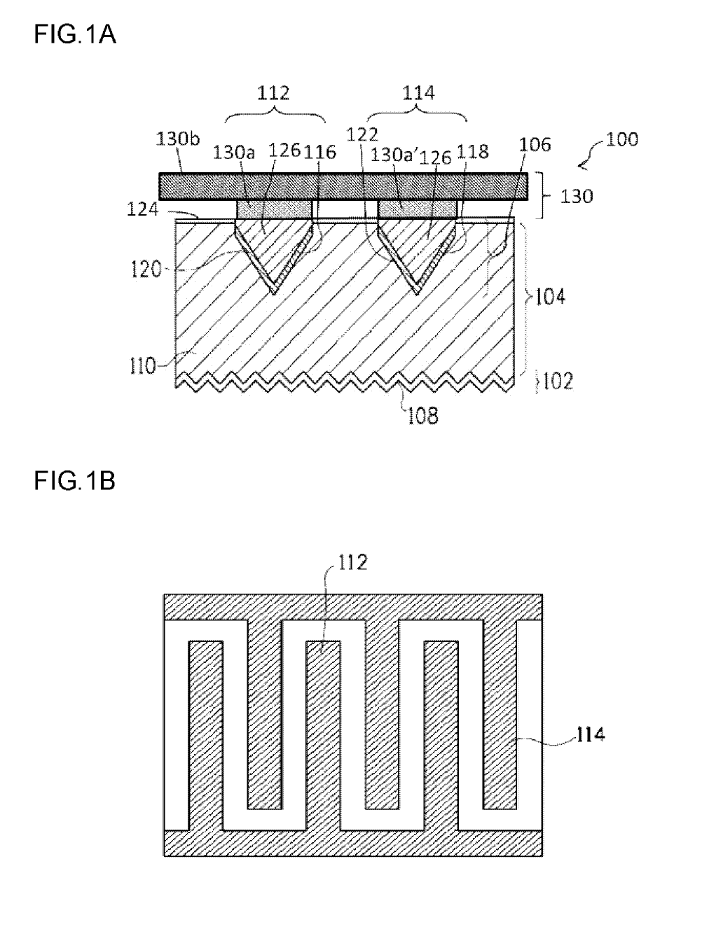

Usually, in cases where such solar cell electrodes are formed using a paste having a high glass frit content as disclosed in this application, there are problems that the electrodes disadvantageously have an increased resistance value (in particular, resistance value in the line directions), bubble generation and so on. However, in this solar cell module, as shown in FIG. 1A, electrodes 126 on the silicon substrate have been matched with and superposed on wiring lines (130a, 130b) constituted of metal foil and formed on the printed wiring board (PWB). Due to this, the line-direction conductivity of the electrodes is basically sufficiently ensured by the wiring lines (130a, 130b). Furthermore, since the electrodes 126 formed on the silicon substrate are configured so that the electrodes 126 are united with the wiring lines (130a, 130b) formed on the printed wiring board, the thickness of the electrodes 126 themselves to be formed on the silicon substrate can be extremely small as compared with ordinary electrodes. In one embodiment, the thickness of the electrodes is 10 μm or less. Since the electrodes 126 are thus formed as thin layers, gas generation is less apt to occur during the electrode formation and even if gas generation occurs, the gas is easy to escape. Consequently, bubble generation has been also inhibited. Furthermore, at the contact interface between the electrodes 126 and the silicon substrate 110, a low value of contact resistance is ensured. In the invention, a low value of contact resistance between the electrodes and the substrate and the satisfactory line-direction conductivity of the electrodes are ensured as described above. It is hence thought that electrodes which as a whole have excellent conductivity are provided. In addition, because of the high glass frit content in the paste, the cost of the production as a whole can be reduced and the invention is also advantageous from the standpoint of profitability.

Here, the contact resistance means the resistance measured at the contact interface between each electrode and the silicon substrate. With respect to the electrodes of a solar cell, it is generally important to reduce the line-direction resistance value of each electrode and the resistance value measured at the contact interface between each electrode and the silicon substrate, from the standpoint of lowering the resistance value of the cell as a whole. In the case where the solar cell has a configuration of the type in which solar cells are superposed on the printed wiring board disclosed in this application and are assembled into a module, the line-direction conductivity of each electrode has already been sufficiently ensured by the wiring lines formed on the printed wiring board, as stated above. It is therefore important to reduce the value of resistance measured at the contact interface between each electrode and the silicon substrate (contact resistance value). This contact resistance value can be calculated from the values measured by the four-terminal method, as will be shown later in Examples.

4. Organic Medium

The conductive composition comprises an organic medium, which comprises resin and solvent. In an embodiment, the organic medium can comprise pine oil solution, ethylene glycol monobutyl ether monoacetate solution or ethyl cellulose terpineol solution of a resin (such as polymethacrylate) or ethyl cellulose. In one embodiment, the terpineol solution of ethyl cellulose (ethyl cellulose content: 5.0 to 50.0 wt %) can be used as the organic medium. In one embodiment, the content of the organic medium is 5.0 to 80.0 wt %, based on the total weight of the conductive composition. In another embodiment, the content is 10.0 to 80.0 wt %, based on the total weight of the conductive composition.

5. Additives

A thickener and/or stabilizer and/or other typical additives may be or may not be added to the conductive composition. Examples of other typical additives that can be added include dispersants and viscosity adjusters. The amount of additive is determined dependent upon the characteristics of the ultimately required conductive composition. The amount of additive can be suitably determined by a person with ordinary skill in the art. Furthermore, a plurality of types of additives may also be added.

As is explained below, the conductive composition has a viscosity within a predetermined range. A viscosity adjuster can be added as necessary to impart a suitable viscosity to the conductive composition. Although the amount of viscosity adjuster added changes dependent upon the viscosity of the conductive composition, it can be suitably determined by a person with ordinary skill in the art.

The conductive composition can be produced as desired by mixing each of the above-mentioned compositions with a roll mixing mill or rotary mixer and the like. The conductive composition can be printed onto a desired site on the back side of a solar cell by screen printing, nozzle printing and the like. The conductive composition has a predetermined viscosity range. In one embodiment, the viscosity of the conductive composition is 50 to 350 Pa·s, in the case of using a #14 spindle with a Brookfield HBT viscometer and measuring using a utility cup at 10 rpm and 25° C.

As has been described above, the composition having conductivity is used to form electrodes on the opposite side from the light receiving side of a solar cell module. Namely, the conductive composition is printed and dried on the opposite side from the light receiving side of a solar cell.

Firing after drying is carried out at temperature of 450° C. to 700° C., in one embodiment, 500° C. to 650° C. in another embodiment. Conventionally, the mixture of silver particles and aluminum particles was occasionally used. The paste containing Al particle requires a firing at a high temperature to form an alloy of Si and Al, which delivers a good contact resistance. However, in case that the paste containing Al is applied for back-contact electrode, sintering high temperature may infer a problem in terms of good P-N junctions. In other words, the Al easily diffuses into the substrate and brings damage since the P-N junction is very thin at the back side of solar cell. Sintering at a low temperature offers the advantages of reducing damage to P-N junctions, decreasing susceptibility to the occurrence of destruction caused by thermal damage and lowering costs.

Printed Wiring Board

In one embodiment, the printed wiring board comprises a substrate, a cathode and anode. In one embodiment, the cathode and anode are placed in a way that the anode and the cathode are in contact with the n+ electrode and the p+ electrode respectively. Examples of the material of the substrate in one embodiment include materials that do not transmit electricity, such as Bakelite and epoxy resins. The shape of the substrate may be platy, filmy, etc. The cathode and the anode are constituted of, for example, copper foil, etc. In one embodiment, the anode and cathode in the printed wiring board have been bonded through a conductive adhesion layer respectively to the n+ electrode and p+ electrode formed on the silicon substrate. In one embodiment, the conductive adhesion layer has been formed from a conductive adhesive, such as a silver paste or a soldering paste, a conductive tape, etc.

In one embodiment, the printed pattern of the anode and the cathode on the printed wiring board corresponds to a pattern of the n+ electrode and the p+ electrode. In this configuration, the satisfactory line-direction conductivity of the electrodes is ensured. Since the electrodes formed from a conductive composition having the aforementioned composition are sufficiently low also in contact resistance between the electrodes and the silicon substrate, a solar cell module which as a whole is excellent in terms of low resistance is provided. The thickness of the printed wiring board is not particularly limited, and is 1-2 mm in one embodiment.

The following provides an explanation of a back-contact solar cell module using the above conductive composition and an explanation of a production process of back contact solar cell electrodes using the example of a solar cell module having the structure shown in FIG. 1, while also providing an explanation of an example of the fabrication of a solar cell.

### Solar Cell Module

The following provides an explanation of a back-contact solar cell module and an explanation of a production process of back-contact solar cell module. The scope of the present invention is not limited to the specific embodiment explained below.

FIG. 1A is a cross-sectional drawing of a portion of a back-contact solar cell module. FIG. 1B is an overhead view showing a portion of an electrode pattern on the opposite side from the light receiving side. A solar cell module 100 is composed of a light receiving section 102, a carrier generating section 104, an electrode section 106 and printed wiring board (PWB) 130. The light receiving section 102 has a textured structure, and the surface thereof is covered with an anti-reflective film 108. The anti-reflective film 108 is a thin film composed of, for example, titanium dioxide (TiO₂) and silicon dioxide (SiO₂). As a result of the light receiving section 102 having a textured structure covered by this anti-reflective film 108, more incident light enters the carrier generating section 104, thereby making it possible to increase the conversion efficiency of the solar cell module 100.

The carrier generating section 104 is composed of a semiconductor 110. When light from the light receiving section 102 (and particularly light having energy equal to or greater than the band gap of the semiconductor 110) enters this semiconductor 110, valence band electrons are excited to the conduction band, free electrons are generated in the conduction band, and free holes are generated in the valence band. These free electrons and free holes are referred to as carriers. If these carriers reach the electrode section 106 by diffusion prior to being recombined in the carrier generating section 104, a current can be obtained from the electrode section 106. Thus, in order to increase the conversion efficiency of the solar cell module 100, it is preferable to use a semiconductor that impairs carrier recombination (namely, has a long carrier life). For this reason, the semiconductor 110 used in the carrier generating section 104 is, for example, crystalline silicon having high resistance.

The electrode section 106 is a section where current generated in the carrier generating section 104 is obtained. This electrode section 106 is formed on the opposite side from the side of the light receiving section 102 of the semiconductor 110.

The electrode section 106 has an anode 112 and a cathode 114, and these are alternately formed on the opposite side from the side of the light receiving section 102 of the semiconductor 110. The anode and the cathode are respectively formed in the form of V grooves 116 and 118 having triangular cross-sections. A p+ region 120 is formed in the V groove 116 of the anode, while an n+ region 122 is formed in the V groove 118 of the cathode. The surface of the side opposite from the side of the light receiving section 102 is covered with an oxide film 124. In addition, electrodes 126 formed from the above conductive composition are embedded in the V grooves.

The printed wiring board (PWB) 130 comprises copper electrodes 130a, 130a′ and a substrate 130b. In the solar cell module 100, the current flowing in from the copper electrode 130a passes through the electrode 126 formed on the p+ region 120, the p+ region 120, the semiconductor 110, the n+ region 122, and the electrode 126 formed on the n+ region 122 to the copper electrode 130a′. When the values of the contact resistance (Rc) between the electrode 126 and p+ region 120 formed in the silicon substrate and between the electrode 126 and n+ region 122 formed in the silicon substrate are low, the cell module 100 has an excellent photoelectric conversion efficiency. Incidentally, in the invention, these values of contact resistance (Rc) there between are calculated from the values measured by the four-terminal method, as will be shown later in Examples.

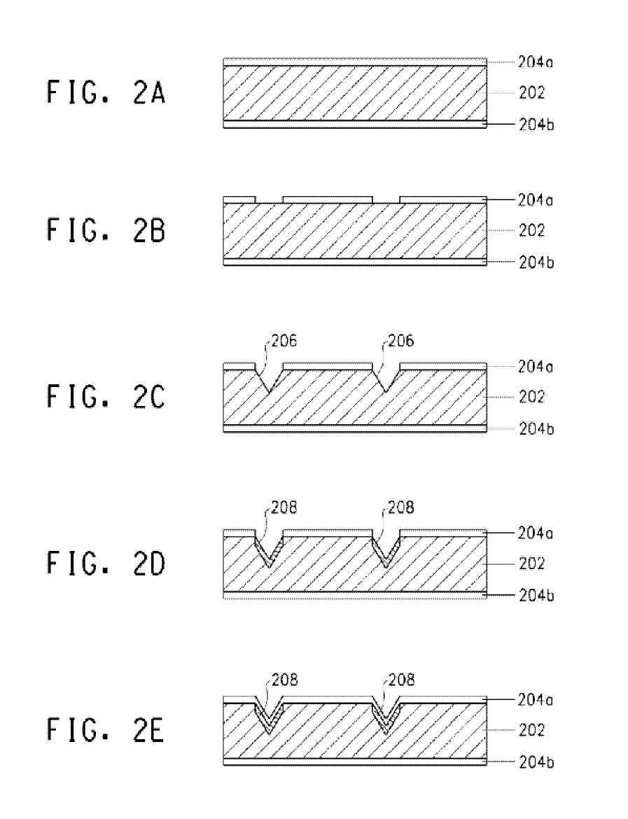

Next, an explanation is provided of the production process of the back-contact solar cell along with an explanation of the production process of a back- contact solar cell with reference to FIGS. 2 to 5.

### Solar Cell Module Production Process

The solar cell electrode production process comprises the following steps of: (1) applying a paste containing 11.0-39.9 wt % silver particles, 10.0-40.0 wt % glass frit, and 0.5-20.0 wt % palladium particles, based on the total weight of the paste; on to the opposite side from the light receiving side of a back contact-type solar cell wafer; and (2) firing the applied paste and the silicon wafer.

First, an explanation is provided of the production a back-contact solar cell wafer used to produce back-contact solar cell electrodes with reference to FIGS. 2 to 4.

A high-resistance silicon wafer 202 (having a thickness of, for example, 250 μm) is prepared, and oxide films 204a and 204b are formed on both sides thereof (FIG. 2A). These oxide films can be formed by, for example, thermal oxidation. Next, the oxide film 204a on one side of the silicon wafer is removed by photolithography or laser etching to leave stripes of a predetermined width (for example, width of 100 μm and interval of 300 μm) (FIG. 2B).

Next, anisotropic etching is carried out with potassium hydroxide (KOH) or tetramethyl ammonium hydroxide (TMAH) on the side from which a portion of the oxide film has been removed, to form V grooves 206 (at an interval of, for example, 300 μm) in the form of stripes having a triangular cross-section (FIG. 2C).

Next, the wafer in which the V grooves 206 have been formed is placed in a diffusion furnace to diffuse the phosphorous. As a result of these steps, an n⁺-region 208 is formed on the portions of the silicon where the V grooves 206 have been formed as shown in FIG. 2D. In the diffusion furnace, by interrupting the gas serving as the phosphorous material and introducing only oxygen, the surfaces of the V grooves 206 can be covered with an oxide film (FIG. 2E).

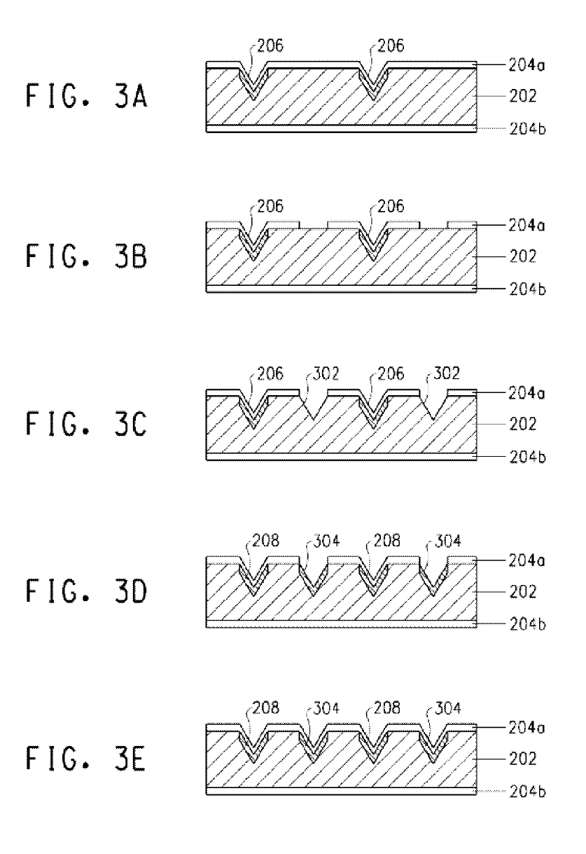

The oxide film is then removed from the substrate obtained in this manner (FIG. 3A) at equal intervals by photolithography or laser etching at the portions between the V grooves 206 of the oxide film 204a (FIG. 3B). For example, in the case the oxide film portion between V grooves 206 has a width of 300 the oxide film is removed so that the distance from V grooves 206 on both sides of this oxide film portion is 100 μm.

Next, anisotropic etching is carried out with potassium hydroxide (KOH) or tetramethyl ammonium hydroxide (TMAH) and so on at those locations where the oxide film has been removed to form V grooves 302 (at a width of, for example, 100 μm) in the form of stripes having a triangular cross-section (FIG. 3C).

Next, the wafer in which V grooves 302 have been formed is placed in a diffusion furnace to diffuse the boron. As a result, as shown in FIG. 3D, a p⁺-type silicon wafer 304 is formed on the silicon portions of V grooves 302. In the diffusion furnace, by interrupting the gas serving as the boron material and introducing oxygen only, the surfaces of the V grooves 302 can be covered with an oxide film (FIG. 3E).

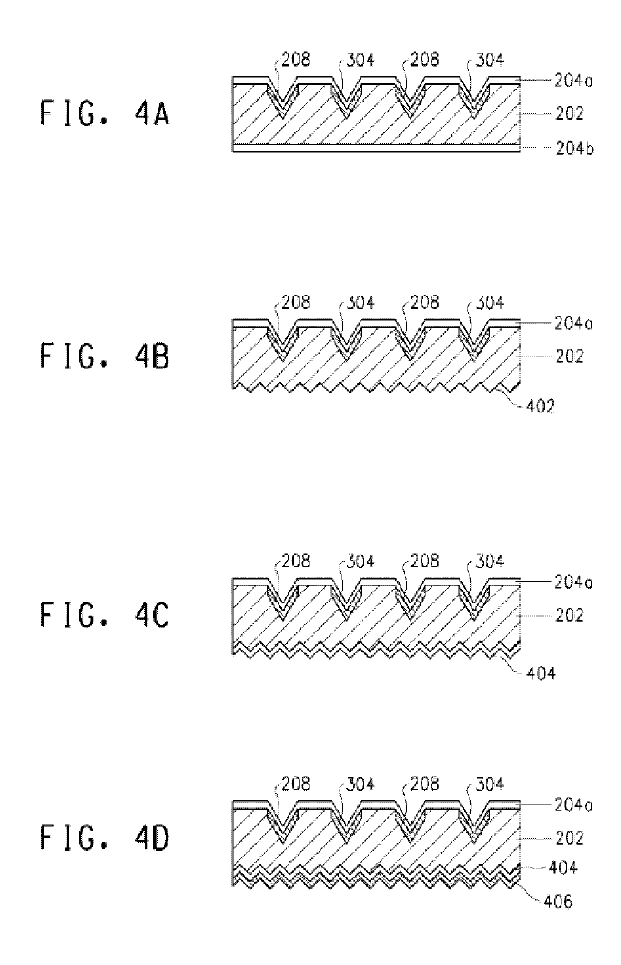

After removing the oxide film on the other surface (the surface on which the oxide film 204b is formed) of the silicon wafer 202 in which two types of V grooves have been formed in this manner (FIG. 4A), anisotropic etching is carried out with potassium hydroxide (KOH) or tetramethyl ammonium hydroxide (TMAH) and so on to form a textured structure 402 in the form of stripes having a triangular cross-section (FIG. 4B). By then carrying out dry oxidation in a diffusion furnace, an oxide film 404 is formed on the other side of the wafer (FIG. 4C).

Subsequently, titanium dioxide (TiO₂), for example, is then deposited on the side of the oxide film 404 at normal temperatures by sputtering and so on (titanium dioxide film: 406). As a result, a light receiving side having an anti-reflective film with a textured structure is formed on the other side of the wafer.

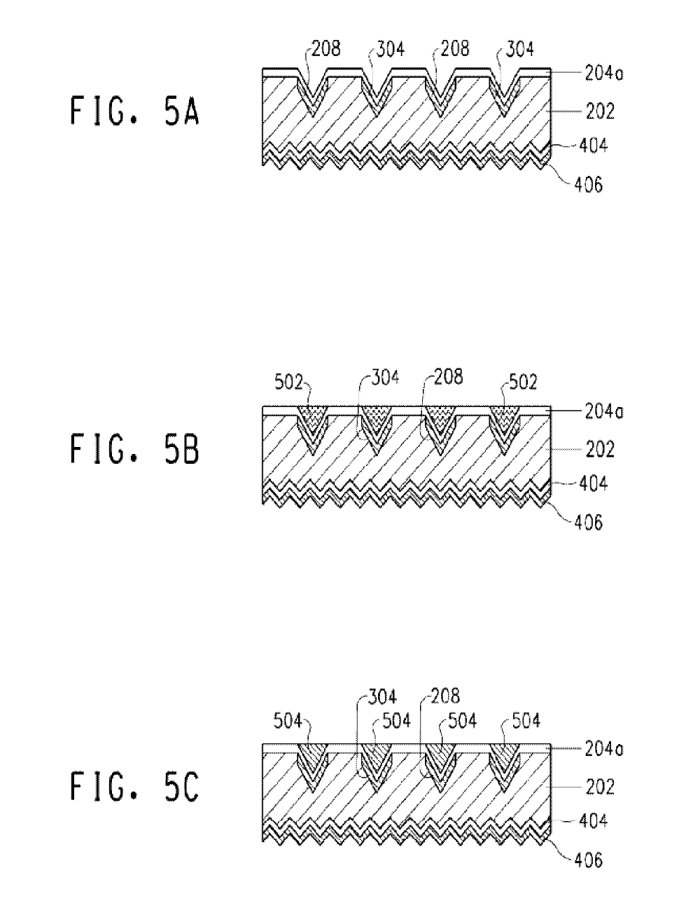

Next, electrodes are formed using the above-disclosed conductive composition. In this step, the conductive composition 502 is embedded in the V grooves (FIG. 5B) of the wafer obtained using the method described above (FIG. 5A). Embedding of the conductive composition can be carried out by a patterning method such as screen printing, stencil printing or dispenser applying.

Next, the wafer filled with the conductive composition (FIG. 5B) is fired at a predetermined temperature (for example, 450 to 900 degree C.) (FIG. 5C). As a result, electrodes 504 are formed.

In one embodiment, in the case of an oxide film being formed on the n⁺-type silicon layer 208 and the p⁺-type silicon layer 304, by firing the conductive composition to fire through the oxide film during formation of the electrodes, the electrode material is coupled directly to the semiconductor and electrical contact is formed. Back-contact solar cell electrodes are produced according to the process shown in FIG. 5.

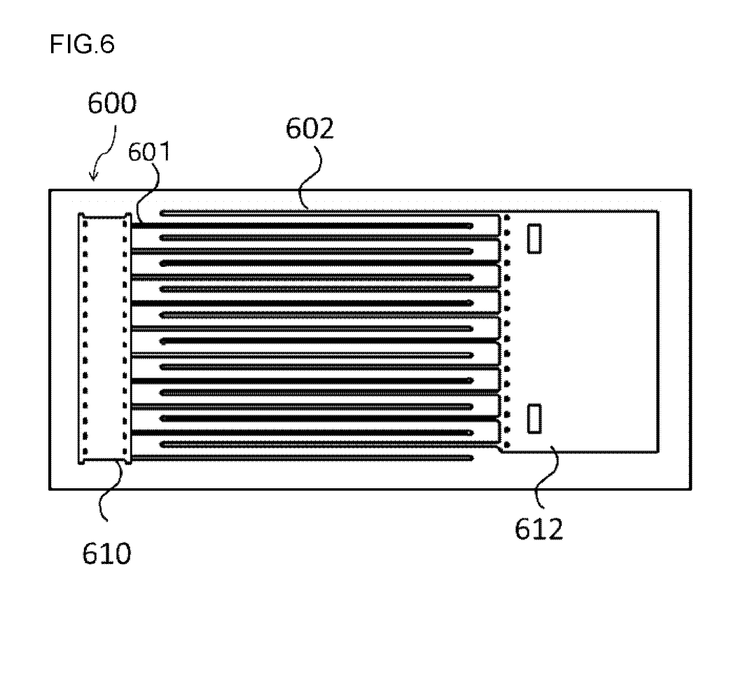

Next, a printed wiring board 600 having the structure diagrammatically shown in FIG. 6 is prepared. The wiring lines 601 (cathode) for p type on the printed wiring board 600 have been formed so as to conform to the pattern of the p+ electrode obtained above, and the wiring lines 602 (anode) for n type on the printed wiring board 600 have been formed so as to conform to the pattern of the n+ electrode obtained above. The wiring lines 601 for p type on the printed wiring board 600 are electrically connected to wiring 610 for connection. The wiring lines 602 for n type on the printed wiring board 600 are electrically connected to wiring 612 for connection. This configuration enables adjacent back-side electrode type solar cells to be electrically connected serially or in parallel through the wiring 610 and 612 for connection. By disposing solar cells on the printed wiring board 600 on which the wiring lines and the wiring have been formed as shown above, so that both the n+ electrodes and the p+ electrodes are electrically connected suitably, a solar cell module is assembled.

### EXAMPLES

Although the following provides an explanation of the present invention through examples thereof, the present invention is not limited to these examples.

### I) Preparation of Conductive Compositions

Conductive pastes E1-E13 and C1-C9 were produced to have the compositions shown in Table 1 using the materials indicated below.

### (i) Silver Particles:

Flaked Silver Particles (D50=2.7 μm (as determined with a laser scattering-type particle size distribution measuring apparatus))

### (ii) Palladium Particles:

Spherical Palladium Particles (D50=2.0 μm (as determined with a laser scattering-type particle size distribution measuring apparatus))

(iii) Glass Frit:

Leaded: Lead borosilicate glass frit

Compositions: SiO₂/PbO/B₂O₃/ZnO

Softening point: 440° C.

Lead-free: Lead-free bismuth glass frit

Compositions: SiO₂/Al₂O₃/B₂O₃/ZnO/Bi₂O₃/SnO₂

Softening point: 390° C.

### (iv) Organic Medium:

A mixture of 10% ethyl cellulose resin (Aqualon, Hercules) and 90% Terpineol solvent

TABLE 1

| Con- | Silver | Palladium | Glass | Organic | | |
|---|---|---|---|---|---|---|
| ductive | Particles | Particles | Frit | Medium | Total | Solid |
| Paste | (wt %) | (wt %) | (wt %) | (wt %) | (wt %) | (wt %) |
| E1 | 38.0 | 1.4 | 11.7 | 48.9 | 100 | 51.1 |
| E2 | 35.9 | 1.4 | 13.8 | 48.9 | 100 | 51.1 |
| E3 | 29.0 | 1.4 | 20.7 | 48.9 | 100 | 51.1 |
| E4 | 22.1 | 1.4 | 27.6 | 48.9 | 100 | 51.1 |
| E5 | 15.2 | 1.4 | 34.5 | 48.9 | 100 | 51.1 |
| E6 | 13.0 | 1.4 | 36.7 | 48.9 | 100 | 51.1 |
| C1 | 49.7 | 1.4 | 0.0 | 48.9 | 100 | 51.1 |
| C2 | 46.3 | 1.4 | 3.4 | 48.9 | 100 | 51.1 |
| C3 | 40.3 | 1.4 | 9.4 | 48.9 | 100 | 51.1 |
| C4 | 10.6 | 1.4 | 39.1 | 48.9 | 100 | 51.1 |
| C5 | 8.3 | 1.4 | 41.4 | 48.9 | 100 | 51.1 |
| E7 | 36.6 | 0.7 | 13.8 | 48.9 | 100 | 51.1 |
| E8 | 34.6 | 2.7 | 13.8 | 48.9 | 100 | 51.1 |
| E9 | 33.8 | 3.7 | 13.8 | 48.9 | 100 | 51.1 |
| E10 | 28.0 | 9.3 | 13.8 | 48.9 | 100 | 51.1 |
| E11 | 18.7 | 18.6 | 13.8 | 48.9 | 100 | 51.1 |
| E12 | 21.7 | 1.0 | 15.4 | 61.9 | 100 | 38.1 |
| E13 | 16.5 | 1.0 | 20.6 | 91.9 | 100 | 38.1 |
| C6 | 37.3 | 0.0 | 13.8 | 48.9 | 100 | 51.1 |
| C7 | 37.2 | 0.1 | 13.8 | 48.9 | 100 | 51.1 |
| C8 | 37.1 | 0.2 | 13.8 | 48.9 | 100 | 51.1 |
| C9 | 36.9 | 0.4 | 13.8 | 48.9 | 100 | 51.1 |

The silver particles, palladium particles, glass frit, resin and solvent were each weighed, mixed and kneaded with a three-roll kneader to obtain silver pastes.

### II) Evaluation Method and Results

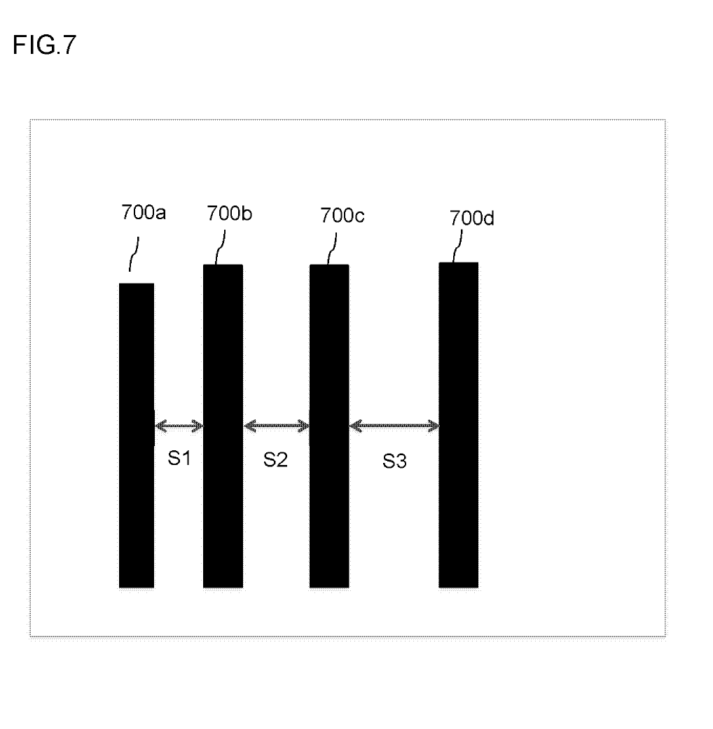

i) The pastes prepared in I) were used to produce samples in the following manner. A mask having pad portions 700a to 700d (1 mm×10 mm; distances between the pad portions are S1=1 mm, S2=2 mm, and S3=3 mm) as shown in FIG. 7 was used to form a pattern of each paste on a silicon substrate by screen printing. Incidentally, two kinds of substrates, i.e., an N substrate and a P substrate, were used as the silicon substrate. Thereafter, the silicon substrate having the paste printed thereon was dried with a 150° C. hot plate for 90 seconds and then fired under the following conditions. Thus, samples each having electrodes formed on the silicon substrate were obtained.

Firing Conditions:

The wafers were fired under the following conditions using an IR heating belt furnace. Maximum set temperature: 650° C., Belt speed: 370 cpm Furnace temperature profile: 400° C. or higher: 18 seconds/500° C. or higher 12 seconds

ii) With respect to each fired sample, the value of contact resistance (Rc) at the interface between the electrodes and the silicon substrate was determined by the following method.

First, probes are placed on two arbitrary electrodes and the value of resistance (R) was obtained by the four-terminal method under the measuring conditions of 10 mA. The value of resistance (R) obtained by this measurement is expressed by the equation: resistance value (R)=2Rc+Rs, where Rc is the value of contact resistance at the contact interface between each electrode and the silicon substrate and Rs is the value of resistance of the silicon substrate located between these two arbitrary electrodes.

Next, the distance between these two electrodes was measured. The data was plotted with the measured distance between the two electrodes on the X-axis and the value of resistance (R) obtained above on the Y-axis.

This procedure was conducted with respect to other combinations of two arbitrary electrodes, and this data was plotted. Finally, Y-intercept (2Rc) was determined by the least squares method and thereby the value of contact resistance (Rc) at the contact interface between the electrodes and the silicon substrate was determined. The results are shown in Table 2.

TABLE 2

| | Conductive | Resistance Values Rc (Ω)* | |
|---|---|---|---|
| Example No. | Paste | N | P |
| Example 1 | E1 | 0.34 | 0.69 |
| Example 2 | E2 | 0.37 | 0.85 |
| Example 3 | E3 | 0.33 | 0.73 |
| Example 4 | E4 | 0.39 | 0.82 |
| Example 5 | E5 | 0.53 | 1.20 |
| Example 6 | E6 | 0.59 | 1.34 |
| Comparative Example 1 | C1 | 0.62 | 4.01 |
| Comparative Example 2 | C2 | 0.49 | 1.62 |
| Comparative Example 3 | C3 | 0.4 | 1.53 |
| Comparative Example 4 | C4 | 0.84 | 1.78 |
| Comparative Example 5 | C5 | 1.52 | 4.5 |
| Example 7 | E7 | 0.39 | 1.02 |
| Example 8 | E8 | 0.33 | 0.86 |
| Example 9 | E9 | 0.39 | 0.48 |
| Example 10 | E10 | 0.57 | 0.8 |
| Example 11 | E11 | 0.69 | 0.85 |
| Example 12 | E12 | 0.37 | 1.20 |
| Example 13 | E13 | 0.44 | 1.10 |
| Comparative Example 6 | C6 | Not measurable | Not measurable |
| Comparative Example 7 | C7 | Not measurable | 2.21 |
| Comparative Example 8 | C8 | 0.58 | 1.9 |
| Comparative Example 9 | C9 | 0.46 | 2.19 |

In the Examples, so long as the value of resistance (Rc) of the N substrate was 0.7Ω or less and the value of resistance (Rc) of the P substrate was 1.4Ω or less, the substrates were rated to be capable of achieving a low resistance value on a practically satisfactory level when solar cells are superposed on the printed wiring boards (PWB) (on the wiring) to assemble solar cell modules.

What is claimed is:

1. A back-contact solar cell module, comprising:
a silicon wafer having a sunlight receiving surface and a rear surface, wherein n+ region and p+ region are formed on the rear surface;
an n+ electrode formed on the n+ region of the silicon wafer;
a p+ electrode formed on the p+ region of the silicon wafer;
a printed wiring board comprising a substrate, a cathode and an anode, being placed in a way that the anode and the cathode are in contact with the n+ electrode and the p+ electrode respectively;
wherein at least one of the n+ electrode and the p+ electrode, prior to firing, comprises a conductive composition comprising 11.0-39.9 wt % of silver particles, 10.0-40.0 wt % of glass frit, and 0.5-20.0 wt % of palladium particles, based on total weight of the composition.

2. The back-contact solar cell module of claim 1, wherein a printed pattern of the anode and the cathode on the printed wiring board corresponds to a pattern of the n+ electrode and the p+ electrode.

3. The back-contact solar cell module of claim 1, wherein both of the n+ electrode and the p+ electrode, prior to firing, comprise a conductive composition comprising 11.0-39.9 wt % of silver particles, 10.0-40.0 wt % of glass frit, and 0.5-20.0 wt % of palladium particles, based on total weight of the composition.

4. The back-contact solar cell module of claim 1, wherein the content of the silver particles is 13.0-39.0 wt %, based on the total weight of the composition.

5. The back-contact solar cell module of claim 1, wherein the content of the glass frit is 11.7-36.7 wt %, based on the total weight of the composition.

6. A method for manufacturing back-contact solar cell module, comprising the steps of:
providing a silicon wafer having a sunlight receiving surface and a rear surface, wherein n+ region and p+ region are formed on the rear surface;
applying a first conductive composition on the n+ region of the silicon wafer;
applying a second conductive composition on the p+ region of the silicon wafer;
firing the first conductive composition and the second conductive composition to form an n+ electrode on the n+ region of the silicon wafer and a p+ electrode on the p+ region of the silicon wafer; and
placing a printed wiring board comprising a substrate, a cathode and an anode on the rear surface of the silicon wafer in a way that the anode and the cathode are in contact with the n+ electrode and the p+ electrode respectively;
wherein at least one of the first conductive composition and the second conductive composition comprises a conductive composition comprising 11.0-39.9 wt % of silver particles, 10.0-40.0 wt % of glass frit, and 0.5-20.0 wt % of palladium particles, based on total weight of the composition.

7. The method of claim 6, wherein a printed pattern of the anode and the cathode on the printed wiring board corresponds to a pattern of the n+ electrode and the p+ electrode.

8. The method of claim 6, wherein both of the first conductive composition and the second conductive composition comprises 11.0-39.9 wt % of silver particles, 10.0-40.0 wt % of glass frit, and 0.5-20.0 wt % of palladium particles, based on total weight of the composition.

9. The method of claim 6, wherein the content of the silver particles is 13.0-39.0 wt %, based on total weight of the composition.

10. The method of claim 6, wherein the content of the glass frit is 11.7-36.7 wt %, based on total weight of the composition.
